(19) United States
(12) Patent Application Publication
(10) Pub. No.: US 2024/0274689 A1
(43) Pub. Date: Aug. 15, 2024

(54) HIGH ELECTRON MOBILITY TRANSISTOR AND ELECTRONIC DEVICE INCLUDING THE SAME

(71) Applicant: Samsung Electronics Co., Ltd., Suwon-si (KR)

(72) Inventors: Injun HWANG, Hwaseong-si (KR); Jaejoon OH, Hwaseong-si (KR); Boram KIM, Hwaseong-si (KR); Sunkyu HWANG, Hwaseong-si (KR)

(73) Assignee: Samsung Electronics Co., Ltd., Suwon-si (KR)

(21) Appl. No.: 18/436,512

(22) Filed: Feb. 8, 2024

(30) Foreign Application Priority Data
Feb. 10, 2023 (KR) 10-2023-0017882

(51) Int. Cl. H01L 29/47; H01L 27/095; H01L 29/20; H01L 29/778

(52) U.S. Cl. CPC H01L 29/475; H01L 27/095; H01L 29/2003; H01L 29/7786

(57) ABSTRACT

A HEMT may include a channel layer including a 2DEG as a channel carrier, first and second electrodes separated on the channel layer, a first semiconductor layer on the channel layer between the first and second electrodes and having a greater band gap greater than the channel layer, a gate stack on the first semiconductor layer, and a gate electrode in ohmic contact with the gate stack. The gate stack may include a lower layer contacting the first semiconductor layer, a second semiconductor layer providing a Schottky barrier on the lower layer, and an upper layer on the second semiconductor layer. The upper layer may be doped with a p-type dopant and may have a lower band gap than the second semiconductor layer.

### CROSS-REFERENCE TO RELATED APPLICATIONS

This application is based on and claims priority under 35 U.S.C. § 119 to Korean Patent Application No. 10-2023-0017882, filed on Feb. 10, 2023 in the Korean Intellectual Property Office, the disclosure of which is incorporated by reference herein in its entirety.

### BACKGROUND

### 1. Field

Example embodiments of the present disclosure relate to a switching device, and more particularly, to a high electron mobility transistor (HEMT) and an electronic device including the same.

### 2. Description of the Related Art

Various power conversion systems may include a device that controls the flow of current through on/off switching of a power device. In a power conversion system, the efficiency of the entire system may depend on the efficiency of the power device.

It has become difficult to increase the efficiency of a power device based on silicon (Si) due to limitations of the physical properties of Si, limitations of a manufacturing process, etc. To overcome such limitations, research and development activities have taken place to improve the efficiency of conversion by applying a compound semiconductor based on a Group III-V such as GaN, etc., to a power device.

Recently, a high electron mobility transistor (HEMT) using a heterojunction structure of a compound semiconductor has been studied. The HEMT may include semiconductor layers having different band gaps. A two-dimensional electron gas (2DEG) may be formed on a semiconductor layer having a small band gap by a semiconductor layer having a large band gap, and the 2DEG may be used as a channel carrier.

### SUMMARY

Provided is a high electron mobility transistor (HEMT) capable of stably maintaining a threshold voltage.

Provided is an HEMT capable of reducing a gate leakage current.

Provided is an electronic device including the HEMT.

Additional aspects will be set forth in part in the description which follows and, in part, will be apparent from the description, or may be learned by practice of the presented embodiments.

According to an embodiment, a high electron mobility transistor (HEMT) may include a channel layer including a two-dimensional (2D) electron gas (2DEG) as a channel carrier; a first electrode and a second electrode separated from each other on the channel layer; a first semiconductor layer on the channel layer between the first electrode and the second electrode, a band gap of the first semiconductor layer being greater than a band gap of the channel layer; a gate stack on the first semiconductor layer; and a gate electrode in ohmic contact with the gate stack. The gate stack may include a lower layer contacting the first semiconductor layer, a second semiconductor layer on the lower layer, and an upper layer on the second semiconductor layer. A band gap of the lower layer may be less than a band gap of the first semiconductor layer. The lower layer may be doped with a p-type dopant. The second semiconductor layer may be a Schottky barrier on the lower layer. A band gap of the second semiconductor layer may be greater than a band gap of the lower layer. A band gap of upper layer may be less than a band gap of the second semiconductor layer. The upper layer may be doped with a p-type dopant.

In some embodiments, a thickness of the second semiconductor layer may be thicker than a thickness of the first semiconductor layer.

In some embodiments, a doping concentration of the upper layer may be greater than a doping concentration of the lower layer.

In some embodiments, the gate stack may further include a third semiconductor layer separated from the second semiconductor layer. The third semiconductor layer may be between the second semiconductor layer and the upper layer. A band gap of the third semiconductor layer may be greater than a band gap of the lower layer and a band gap of the upper layer.

In some embodiments, a thickness of the second semiconductor layer and a thickness of the third semiconductor layer may be equal to each other.

In some embodiments, a thickness of the second semiconductor layer and a thickness of the third semiconductor layer may be different from each other.

In some embodiments, a material of the second semiconductor layer and a material of the third semiconductor layer may be identical to each other. The second semiconductor layer and the third semiconductor layer may be thicker than the first semiconductor layer.

In some embodiments, the second semiconductor layer and the third semiconductor layer may include compound semiconductors. For example, the compound semiconductor may include a ternary compound semiconductor comprising a Group III-V element.

In some embodiments, the gate stack may further include an intermediate layer between the second semiconductor layer and the third semiconductor layer. A band gap of the intermediate layer may be less than the band gap of the second semiconductor layer and the band gap of the third semiconductor layer. The intermediate layer may be doped with a p-type dopant.

In some embodiments, the thickness of the upper layer may be less than the thickness of the lower layer and a thickness of the intermediate layer.

In some embodiments, a doping concentration of the intermediate layer and a doping concentration of the lower layer may be lower than a doping concentration of the upper layer.

In some embodiments, the lower layer, the intermediate layer, and the upper layer may include compound semiconductors of identical components.

In some embodiments, the first semiconductor layer and the second semiconductor layer may include identical compound semiconductors. For example, the first semiconductor layer and the second semiconductor layer may include a ternary compound semiconductor comprising a Group III-V element.

In some embodiments, the lower layer and the upper layer may include a binary nitride including an identical element of a Group III-V. For example, the binary nitride may include GaN.

In some embodiments, the lower layer, the upper layer, and the second semiconductor layer may include Group III-V ternary compound semiconductors of identical components comprising aluminum, and an aluminum content of the second semiconductor layer may be greater than an aluminum content of the lower layer and an aluminum content of the upper layer.

According to an embodiment, an electronic device may include a plurality of high electron mobility transistors (HEMTs) having different threshold voltages, and one of the plurality of HEMTs may include the HEMT described above.

According to an embodiment, an electronic device may include any one of the HEMTs described above.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a cross-sectional view of a first high electron mobility transistor (HEMT) according to an example embodiment;

FIG. 2 is a cross-sectional view of a second HEMT according to an example embodiment;

FIG. 3 is an energy band diagram of a first gate stack of the first HEMT of FIG. 1;

FIG. 4 is a diagram of an electronic device including a plurality of switching devices according to an example embodiment;

FIG. 5 is a cross-sectional view of a third switching device of FIG. 4, cut in a direction 5-5′;

FIG. 6 is a cross-sectional view of a fourth switching device of FIG. 4, cut in a direction 6-6′;

FIG. 7 is a cross-sectional view of a modification of the second HEMT according to an example embodiment; and

FIGS. 8 to 11 are block diagrams of electronic devices according to an example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of a, b, and c” may be understood to include “only a,” “only b,” “only c,” “a and b,” “a and c,” “b and c,” or “a, b, and c”.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, a high electron mobility transistor (HEMT) and an electronic device including the same according to an example embodiment will be described in detail with reference to the accompanying drawings. In this process, a thickness of a layer or region shown in the drawings may be shown as being slightly exaggerated for clarity of the specification.

Embodiments to be described are merely examples, and various modifications may be made from such embodiments. In a layer structure described below, an expression “above” or “on” may include not only an expression “directly on” and “directly in contact” but also an expression “on contactlessly”. In other words, “A on B” may cover “A directly on B” or “A on B with one or more intervening layers between A and B.” In the following description, the same reference numeral in each drawing may refer to the same member.

Singular forms include plural forms unless apparently indicated otherwise contextually. When a portion is referred to as “comprises” a component, the portion may not exclude another component but may further include another component unless stated otherwise.

The use of the terms of “the above-described” and similar indicative terms may correspond to both the singular forms and the plural forms. When there is no apparent description of the order of operations constituting a method or a contrary description thereof, the operations may be performed in an appropriate order. The disclosure is not necessarily limited according to the describing order of the operations.

The term used herein such as “unit” or “module” indicates a unit for processing at least one function or operation, and may be implemented in hardware, software, or in a combination of hardware and software.

Connections of lines or connection members between components shown in the drawings are illustrative of functional connections and/or physical or circuit connections, and in practice, may be represented as alternative or additional various functional connections, physical connections, or circuit connections.

The use of all examples and terms is only to describe technical spirit in detail, and the scope is not limited by these examples or terms unless limited by the claims.

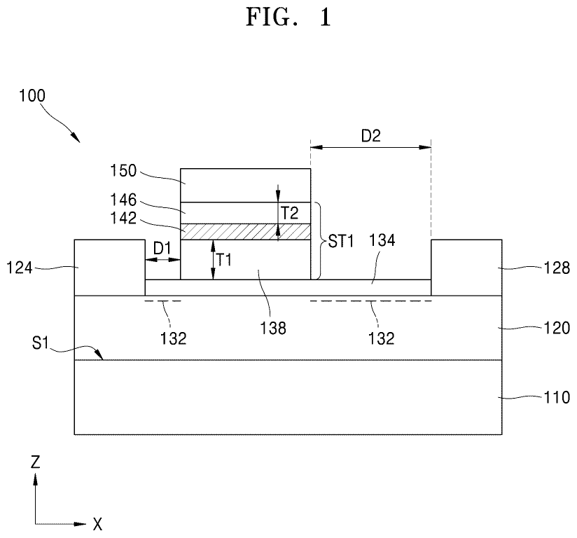

FIG. 1 shows a first high electron mobility transistor (HEMT) 100 according to an example embodiment.

Referring to FIG. 1, the first HEMT 100 may include a substrate 110, a channel layer 120, a first semiconductor layer 134, a first gate stack ST1, and a gate electrode 150, which are sequentially formed, and may include a first electrode 124 and a second electrode 128 provided at both sides of the first semiconductor layer 134, without being limited thereto.

For example, the substrate 110 may include a single material layer or a plurality of material layers. For example, the substrate 110 may be a buffer layer having the channel layer 120 formed thereon. For example, the substrate 110 may include a Group III-V compound semiconductor layer. The channel layer 120 may be formed, without being limited to, in an epitaxial method.

For example, the substrate 110 may include a silicon layer together with the Group III-V compound semiconductor layer. For example, the substrate 110 may be formed by sequentially stacking the silicon layer and the Group III-V compound semiconductor layer. In this case, another material layer (e.g., an AlN layer) may be further provided between the silicon layer and the Group III-V compound semiconductor layer.

For example, the Group III-V compound semiconductor layer may be or may include a GaN layer, without being limited thereto. For example, the Group III-V compound semiconductor layer may be a nitride layer.

The channel layer 120 may be formed on a surface S1 of the substrate 110. The surface S1 may be a top surface, but may also be a side surface, a bottom surface, or an inclined surface depending on a viewpoint. The surface S1 of the substrate 110 may be a surface of the Group III-V compound semiconductor layer. The channel layer 120 may be formed to cover the entire surface S1 of the substrate 110 or a part thereof. For example, a thickness of the channel layer 120 may be equal to that of the substrate 110. For example, the thickness of the channel layer 120 may be equal to or different from that of the substrate 110. For example, the thickness of the channel layer 120 may be equal to or different from that of the Group III-V compound semiconductor layer included in the substrate 110.

For example, the channel layer 120 may be a second Group III-V compound semiconductor layer having a first band gap or may include the second Group III-V compound semiconductor layer, without being limited thereto. For example, the channel layer 120 may include a nitride compound semiconductor layer. For example, the channel layer 120 may be or include a GaN layer, an AlGaN layer, or an InGaN layer, without being limited thereto.

The channel layer 120 may include a two-dimensional electron gas (2DEG) 132 on a surface layer thereof. The first HEMT 100 may be an HEMT in a normally off state. The 2DEG 132 may be distributed such that the first HEMT 100 enters the normally off state. To this end, the 2DEG 132 may exist on a partial region of the surface layer of the channel layer 120. For example, the 2DEG 132 may exist between a first electrode 124 and the first gate stack ST1 and between a second electrode 128 and the first gate stack ST1. A 2DEG 132 on the surface layer of the channel layer 120 below the bottom surface of the first gate stack ST1 (a surface facing the channel layer 120) may be depleted by the first gate stack ST1. Accordingly, the 2DEG 132 may not exist under the first gate stack ST1. For example, the 2DEG 132 may exist under the first gate stack ST1, but a density of the 2DEG 132 may be ignorable (e.g., negligible) because it may be even lower than that of the 2DEG 132 existing between the first and second electrodes 124 and 128 and the first gate stack ST1.

The surface layer of the channel layer 120 may include a surface of the channel layer 120 and the 2DEG 132. The 2DEG 132 may be directly below the surface of the channel layer 120, that is, just below the surface.

The first semiconductor layer 134 may be provided on the surface of the channel layer 120 between the first electrode 124 and the second electrode 128. The surface between the first electrode 124 and the second electrode 128 of the channel layer 120 may be entirely covered with the first semiconductor layer 134, without being limited thereto. Thus, the 2DEG 132 may be completely covered with the first semiconductor layer 134. The first semiconductor layer 134 may be formed to have a first thickness that may be uniform or substantially uniform across the entire area of the first semiconductor layer 134. The first semiconductor layer 134 may be formed on the surface of the channel layer 120 in a growth method, and may also be formed in a stacking method as well as the growth method.

When measured thicknesses of two different regions of the first semiconductor layer 134 are different from each other, the thicknesses of two regions may be regarded as being substantially the same as each other when a difference therebetween falls within an allowable error range or does not affect generation of the 2DEG 132 or an operation of the first HEMT 100.

For example, the first semiconductor layer 134 may have a thickness for forming the 2DEG 132. For example, the first semiconductor layer 134 may have a thickness of about 25 nm or less or about 0.5 nm to about 20 nm, without being limited thereto.

The first semiconductor layer 134 may be a barrier or may be or include a semiconductor layer having a second band gap. The second band gap may be greater than the first band gap of the channel layer 120. The 2DEG 132 may be formed on the channel layer 120 due to a difference of band gaps between the first semiconductor layer 134 and the channel layer 120.

For example, the first semiconductor layer 134 may be or include a ternary compound semiconductor layer including a Group III-V element. For example, the ternary compound semiconductor layer may be, but not limited to, a nitride layer. For example, the ternary compound semiconductor layer may include, but not limited to, AlGaN or AlInN.

For example, the first semiconductor layer 134 may include a compound semiconductor layer having a different component or composition while maintaining a nitride. For example, the first semiconductor layer 134 may include a binary (e.g., AlN) or quaternary compound semiconductor (e.g., AlInGaN).

When the first semiconductor layer 134 and the channel layer 120 are material layers having the same component (e.g., AlGaN), the material layers may have different compositions to maintain a difference between the first band gap and the second band gap.

The first electrode 124 may be formed on the channel layer 120 to the left of the first semiconductor layer 134, and the second electrode 128 may be formed on the channel layer 120 to the right of the first semiconductor layer 134. The first electrode 124 may directly contact the channel layer 120 and may be formed as a structure directly contacting the 2DEG 132. A side surface of the first electrode 124, which faces (is adjacent to) the first semiconductor layer 134, may directly contact the first semiconductor layer 134.

The second electrode 128 may directly contact the channel layer 120 and may be formed as a structure directly contacting the 2DEG 132. A side surface of the second electrode 128, which faces (is adjacent to) the first semiconductor layer 134, may directly contact the first semiconductor layer 134. The first electrode 124 and the second electrode 128 may be formed to have the same height or different heights.

The first electrode 124 and the second electrode 128 may be expressed as a first electrode layer and a second electrode layer. In FIG. 1, the first electrode 124 may be a source electrode, and the second electrode 128 may be a drain electrode.

The first gate stack ST1 may be located between the first electrode 124 and the second electrode 128 and may be provided not to contact the first electrode 124 and the second electrode 128. The first gate stack ST1 may directly contact the first semiconductor layer 134, without being limited thereto. The first gate stack ST1 may be located closer to the first electrode 124 than to the second electrode 128. That is, a first distance D1 between the first gate stack ST1 and the first electrode 124 may be, without being limited to, less than a second distance D2 between the first gate stack ST1 and the second electrode 128.

The first gate stack ST1 may include a lower layer 138, a second semiconductor layer 142, and an upper layer 146 that are sequentially stacked on the first semiconductor layer 134 in a vertical direction (e.g., a Z-axis direction). Widths in a horizontal direction (e.g., an X-axis direction) of the lower layer 138, the second semiconductor layer 142, and the upper layer 146 may be the same as or substantially the same as one another. For example, the lower layer 138, the second semiconductor layer 142, and the upper layer 146 may be formed to have different thicknesses.

The lower layer 138 may be formed to have a first thickness T1 that may be uniform or substantially uniform across the entire lower layer 138. For example, the first thickness T1 of the lower layer 138 may be, but not limited to, about 30 nm to about 200 nm or about 50 nm to about 200 nm.

For example, the lower layer 138 may be or include a material layer having a band gap less than the second band gap of the first semiconductor layer 134. For example, the lower layer 138 may be a compound semiconductor layer (a p-type compound semiconductor layer) doped with a p-type conductive impurity or a p-type dopant or include such a material layer. For example, the lower layer 138 may be a p-type compound semiconductor layer including a Group III-V element or include such a material layer. For example, the lower layer 138 may be or include, but not limited to, a p-type GaN layer (p-GaN layer). For example, the lower layer 138 may include a p-type ternary compound semiconductor layer. For example, the lower layer 138 may include, but not limited to, a p-type AlGaN layer and a p-type InGaN layer. For example, when the lower layer 138 is a compound semiconductor layer including aluminum (Al), a content of Al of the lower layer 138 may be, but not limited to, about 5%.

The lower layer 138 may be formed in the growth method or other methods.

The second semiconductor layer 142 may be formed to have a thickness less than the first thickness T1 of the lower layer 138. For example, the second semiconductor layer 142 may have the thickness that is equal to or different from the thickness of the first semiconductor layer 134. For example, the second semiconductor layer 142 may be thicker than the first semiconductor layer 134. For example, the second semiconductor layer 142 may be formed to have a thickness of, but not limited to, about 40 nm or less.

For example, the second semiconductor layer 142 may be a compound semiconductor layer having a band gap greater than that of the lower layer 138 and may serve as a Schottky barrier. Thus, a hole injected into a gate may be controlled in an HEMT operation, and a voltage applied to the gate may be distributed to the first semiconductor layer 134 and the second semiconductor layer 142, thus reducing a gate leakage current. A degree of the hole injected into the gate may be controlled according to a thickness and/or a composition of the second semiconductor layer 142. Thus, the thickness and/or composition of the second semiconductor layer 142 may be determined based on a degree of hole accumulation and a degree of a leakage current.

In this way, as the degree of the hole injected into the gate is controlled by the second semiconductor layer 142, charging of the lower layer 138, e.g., the degree of hole accumulation with respect to the lower layer 138 may be controlled. Thus, a threshold voltage Vth may be maintained stably in an HEMT operation, and the gate leakage current may be reduced in comparison to when the second semiconductor layer 142 is absent.

As the threshold voltage is maintained stably in the HEMT operation in this way, a problem corresponding to an excessive increase of the threshold voltage (e.g., an increase of a dynamic on-resistance and a conduction loss corresponding thereto) and a problem corresponding to a reduction of the threshold voltage (e.g., a power loss and a reliability degradation by an operation at a voltage lower than a set operating voltage and) may be coped with. Moreover, as the gate leakage current decreases, the voltage applied to the gate may increase, such that an HEMT device exemplified as a power conversion device may be applied to a wider range.

For example, the second semiconductor layer 142 may be formed of a material that is the same as or different from that of the first semiconductor layer 134. For example, when the second semiconductor layer 142 is formed as a compound semiconductor layer including Al, a content of Al in the second semiconductor layer 142 may be about 25% or less or about 15% to about 20%.

For example, the second semiconductor layer 142 may be formed, but not limited to, in the growth method. The second semiconductor layer 142 may contact the lower layer 138 and may be formed to cover, but not limited to, the entire top surface of the lower layer 138.

The upper layer 146 may be formed on the top surface of the second semiconductor layer 142 to contact the top surface and cover the entire top surface, without being limited thereto. The upper layer 146 may be formed, but not limited to, in the growth method.

The upper layer 146 may be formed to have a second thickness T2. The second thickness T2 of the upper layer 146 may be uniform or substantially uniform across the entire upper layer 146. For example, the second thickness T2 of the upper layer 146 may be less than, but not limited to, a first thickness T1 of the lower layer 138. For example, the first thickness T1 and the second thickness T2 may be substantially equal to each other.

For example, a band gap of the upper layer 146 may be less than that of the second semiconductor layer 142. For example, the upper layer 146 may be a p+-type Group III-V compound semiconductor layer with a greater doping concentration of a p-type dopant than that of the lower layer 138 or may include such a material layer. A material of the upper layer 146 may be the same as that of the lower layer 138 except for different doping concentrations. For example, the upper layer 146 may include a p+ GaN layer.

The gate electrode 150 may exist on the top surface of the first gate stack ST1 and contact the top surface and may be formed to cover the entire top surface. That is, the gate electrode 150 may be formed to contact the upper layer 146 on the upper layer 146. The horizontal width of the gate electrode 150 may be equal to or substantially equal to the width of the upper layer 146. The gate electrode 150 may form ohmic contact with the upper layer 146. For example, the gate electrode 150 may include, but not limited to, at least one of Ti, TiN, TiAl, and W. The gate electrode 150 may be expressed as a gate electrode layer or a third electrode (layer).

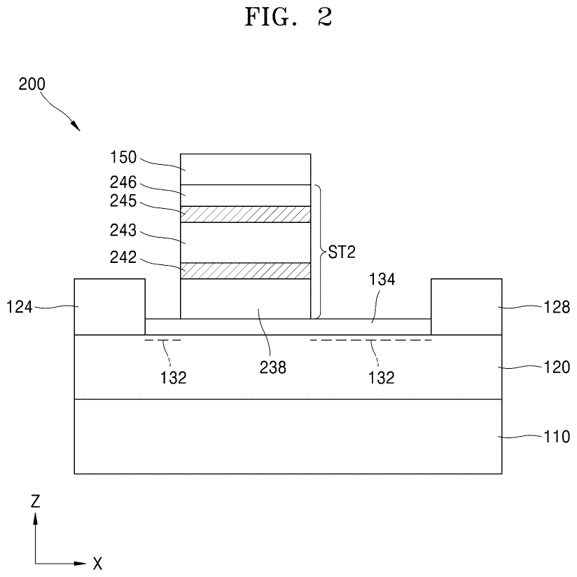

FIG. 2 shows a second HEMT 200 according to an example embodiment. A part that is different from the first HEMT 100 of FIG. 1 will be described.

Referring to FIG. 2, the second HEMT 200 may include a second gate stack ST2 provided between the first semiconductor layer 134 and the gate electrode 150. A bottom surface of the second gate stack ST2 may contact the first semiconductor layer 134 and a top surface thereof may contact the gate electrode 150. The second gate stack ST2 may include a lower layer 238, a third semiconductor layer 242, an intermediate layer 243, a fourth semiconductor layer 245, and an upper layer 246 that are sequentially stacked on the first semiconductor layer 134.

For example, dimensions (e.g., a thickness and a width) and materials of the lower layer 238 may be, but not limited to, the same as those of the lower layer 138 of FIG. 1.

For example, dimensions and materials of the third semiconductor layer 242 may be, but not limited to, the same as those of the second semiconductor layer 142 of FIG. 1.

For example, dimensions and materials of the intermediate layer 243 may be, but not limited to, the same as those of the lower layer 238.

For example, dimensions and materials of the fourth semiconductor layer 245 may be, but not limited to, the same as those of the third semiconductor layer 242.

For example, dimensions and materials of the upper layer 246 may be, but not limited to, the same as those of the upper layer 146 of FIG. 1.

For example, thicknesses of the third semiconductor layer 242 and the fourth semiconductor layer 245 may be equal to or different from each other.

For example, thicknesses of the lower layer 238 and the intermediate layer 243 may be equal to or different from each other.

For example, a thickness of the upper layer 246 may be less than or equal to thicknesses of the lower layer 238 and the intermediate layer 243.

The second gate stack ST2 of the second HEMT 200 may include two semiconductor layers 242 and 245 as Schottky barriers in a p-GaN layer. Thus, a stably maintained threshold voltage of the second HEMT 200 may be different from that of the first HEMT 100. That is, the threshold voltage of the second HEMT 200 may be greater than that of the first HEMT 100, and the gate leakage current of the second HEMT 200 may be less than that of the first HEMT 100.

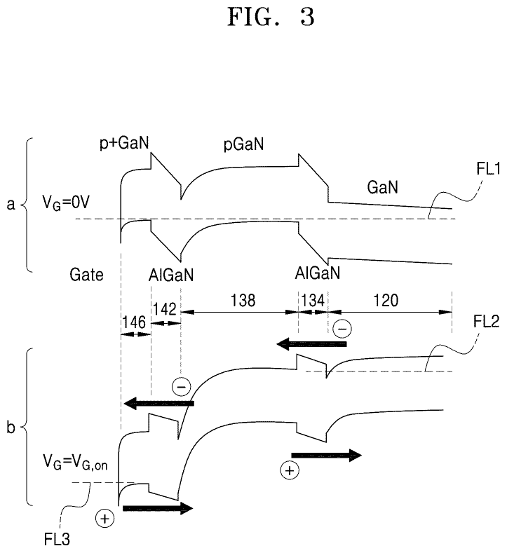

FIG. 3 shows an example of an energy band for the first gate stack ST1 of the first HEMT 100 of FIG. 1 when the channel layer 120 is a GaN layer, the first semiconductor layer 134 and the second semiconductor layer 142 are AlGaN layers, the lower layer 138 is a pGaN layer, and the upper layer 146 is a p+ GaN layer.

In FIG. 3, a shows an energy band when a voltage is not applied to the gate electrode 150 (V_{G}=0), and b shows an energy band when an operating voltage is applied to the gate electrode 150 (V_{G}=V_{G},on). Reference numerals FL1, FL2, and FL3 indicate Fermi levels.

Comparing a and b of FIG. 3, due to existence of the second semiconductor layer 142, hole (+) injection from the upper layer 146 to the lower layer 138 may be limited and electron (−) movement from the channel layer 120 to the upper layer 146 may also be limited.

As an energy band of the second semiconductor layer 142 may vary depending on a thickness and/or a component (Al) content of the second semiconductor layer 142, the degree of hole injection with respect to the lower layer 138 may be controlled and a gate leakage current may be reduced, by adjusting the thickness and/or the component content of the second semiconductor layer 142.

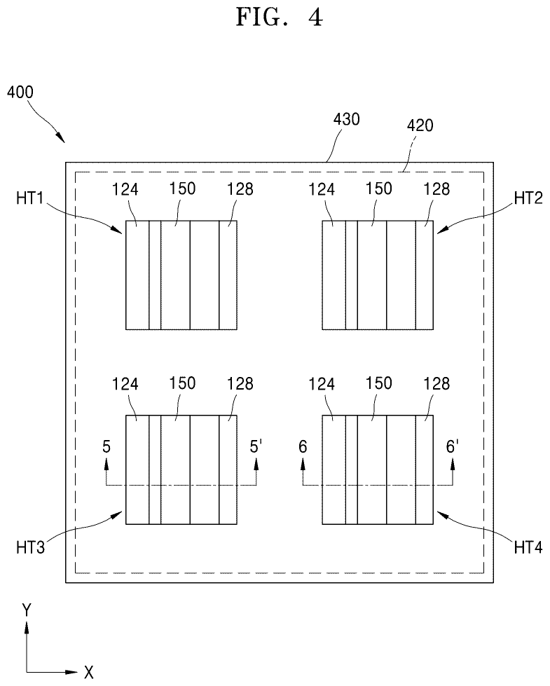

FIG. 4 shows an electronic device including a plurality of switching devices according to an example embodiment in which a chip includes a plurality of HEMTs.

Referring to FIG. 4, an electronic device 400 may include a substrate 430 in which a circuit unit 420 is formed. The circuit unit 420 may include first to fourth switching devices HT1 to HT4 using a 2DEG as a channel carrier. The circuit unit 420 may include unit electronic devices as well as the first to fourth switching devices HT1 to HT4, e.g., but not limited to, at least one of a capacitor, a resistor, and a diode.

For example, the first to fourth switching devices HT1 to HT4 may have different operating threshold voltages. For example, the first switching device HT1 may include a first transistor having a first threshold voltage, the second switching device HT2 may include a second transistor having a second threshold voltage, the third switching device HT3 may include a third transistor having a third threshold voltage, and the fourth switching device HT4 may include a fourth transistor having a fourth threshold voltage. One of the first to fourth switching devices HT1 to HT4 may be an HEMT in a normally on state, and the others may be HEMTs in a normally off state.

For example, the first switching device HT1 may include the first HEMT 100 of FIG. 1.

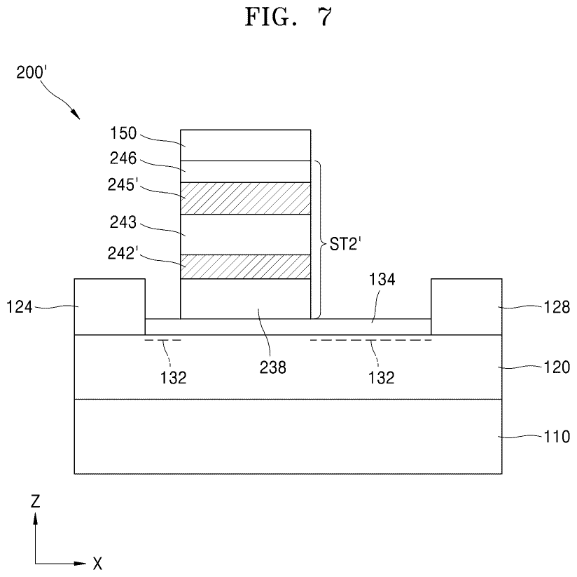

For example, the second switching device HT2 may include the second HEMT 200 of FIG. 2 or the second HEMT 200′ of FIG. 7.

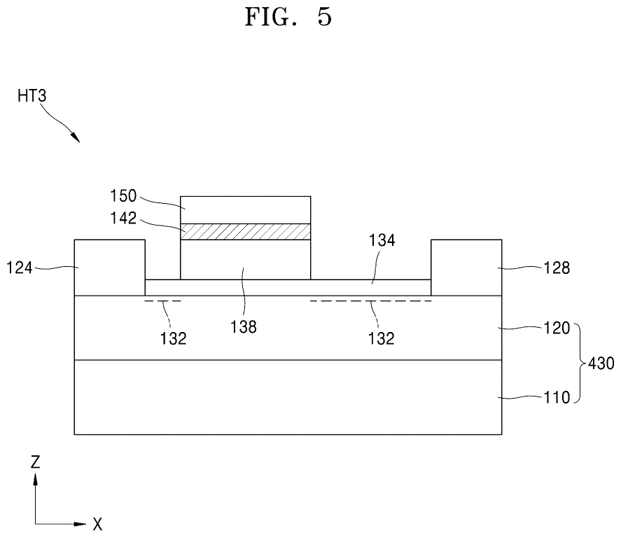

FIG. 5 is a cross-sectional view of the third switching device HT3 of FIG. 4, cut in a direction 5-5′.

Referring to FIG. 5, the third switching device HT3 may be the same as a result of removing the upper layer 146 from the first HEMT 100 of FIG. 1. In the third switching device HT3, the second semiconductor layer 142 may directly contact the gate electrode 150. Thus, the third switching device HT3 may be an HEMT in which the gate electrode 150 and the lower layer 138 form Schottky contact.

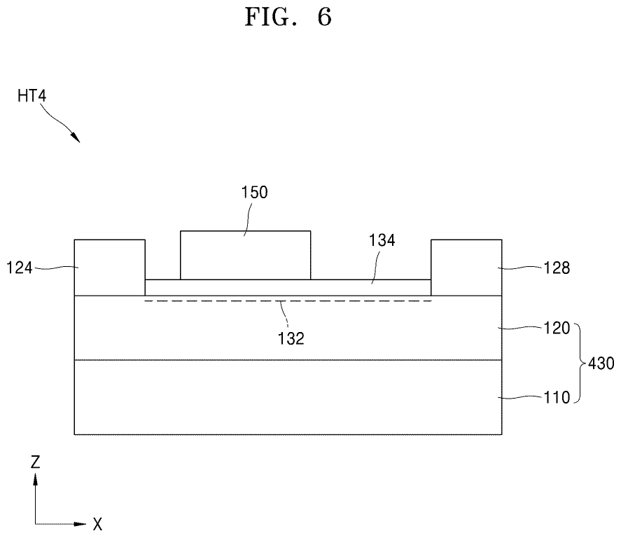

FIG. 6 is a cross-sectional view of the fourth switching device HT4 of FIG. 4, cut in a direction 6-6.

Referring to FIG. 6, the fourth switching device HT4 may be the same as a result of removing the first gate stack ST1 from the first HEMT 100 of FIG. 1 and directly forming the gate electrode 150 on the first semiconductor layer 134. Thus, the 2DEG 132 may exist on the entire surface of the channel layer 120 between the first electrode 124 and the second electrode 128 in the fourth switching element HT4. That is, the fourth switching element HT4 may be an HEMT in the normally on state where the first electrode 124 and the second electrode 128 are connected to each other by the 2DEG 132.

For example, some of the first to fourth switching devices HT1 to HT4 in the electronic device 400 shown in FIG. 4, e.g., a chip may be omitted. For example, the electronic device 400 may include first to third switching devices HT1 to HT3 or two switching devices (e.g., HT1 and HT4 or HT2 and HT4) among the four switching devices HT1 to HT4.

FIG. 7 is a cross-sectional view of a modification of the second HEMT according to an example embodiment.

Referring to FIG. 7, a HEMT 200′ may be the same as the HEMT 200 illustrated in FIG. 2, except the thicknesses of layers in second gate stack ST2′ may be modified. For example, the third semiconductor layer 242′ and the fourth semiconductor layer 245′ may have different thicknesses than each other. A thickness of the fourth semiconductor layer 245′ may be thicker than a thickness of the third semiconductor layer 242′. The third semiconductor layer 242′ and the fourth semiconductor layer 245′ each may be thicker than the first semiconductor layer 134.

Next, an electronic device according to an example embodiment will be described. The electronic device according to an example embodiment may include the HEMT described above as an example.

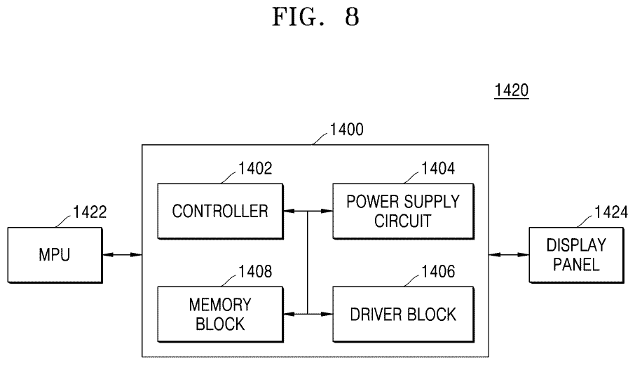

FIG. 8 is a schematic block diagram of a display driver integrated circuit (DDI) 1400 and a display device 1420 including the DDI 1400 as a first electronic device according to an example embodiment.

Referring to FIG. 8, the DDI 1400 may include a controller 1402, a power supply circuit 1404, a driver block 1406, and a memory block 1408. The controller 1402 may receive and decode a command applied from a main processing unit (MPU) 1422 and control each block of the DDI 1400 to implement an operation corresponding to the command. The power supply circuit 1404 may generate a driving voltage in response to control of the controller 1402. The driver block 1406 may drive a display panel 1424 by using the driving voltage generated in the power supply circuit 1404 in response to control of the controller 1402. The display panel 1424 may be a liquid crystal display panel or a plasma display panel. The memory block 1408 may temporarily store a command input to the controller 1402 or control signals output from the controller 1402 or store required data and may include a volatile memory such as random access memory (RAM) and/or a non-volatile memory such as a read only memory (ROM). For example, the units and/or blocks included in the DDI 1400 may include a switching device which may include any one of the above-described HEMTs.

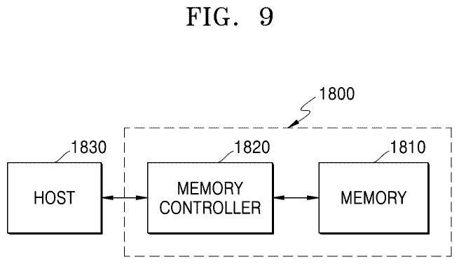

FIG. 9 is a block diagram of an electronic system 1800 as a second electronic device according to an example embodiment.

Referring to FIG. 9, the electronic system 1800 may include a memory 1810 and a memory controller 1820. The memory controller 1820 may control the memory 1810 for data reading from the memory 1810 and/or data writing to the memory 1810, in response to a request of a host 1830.

For example, the memory 1810 and the memory controller 1820 of the electronic system 1800 may include a switching device which may include any one of the above-described HEMTs.

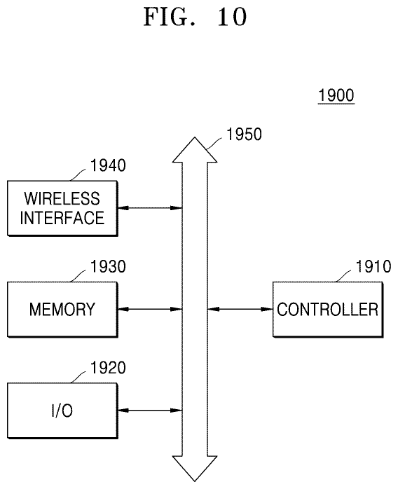

FIG. 10 is a block diagram of an electronic system 1900 as a third electronic device according to an example embodiment.

Referring to FIG. 10, the electronic system 1900 may constitute a wireless communication device or a device capable of transmitting and/or receiving information in a wireless environment. The electronic system 1900 may include a controller 1910, an input/output device I/O 1920, a memory 1930, and a wireless interface 1940, which are connected to one another through a bus 1950.

The controller 1910 may include at least one of a microprocessor, a digital signal processor, and a processing device similar thereto. The input/output device 1920 may include at least one of a keypad, a keyboard, and a display.

The memory 1930 may be used to store a command executed by the controller 1910. For example, the memory 1930 may be used to store user data.

For example, the components 1910, 1920, 1930, and 1940 included in the electronic system 1900 may include a switching device which may include any one of the HEMTs according to the example embodiments described above.

The electronic system 1900 may use the wireless interface 1940 to transmit/receive data through a wireless communication network. The wireless interface 1940 may include an antenna and/or a wireless transceiver. In some embodiments, the electronic system 1900 may be used in a communication interface protocol of a third-generation communication system such as code division multiple access (CDMA), global system for mobile communications (GSM), North American digital cellular (NADC), extended-time division multiple access (E-TDMA), and/or wide band code division multiple access (WCDMA), etc.

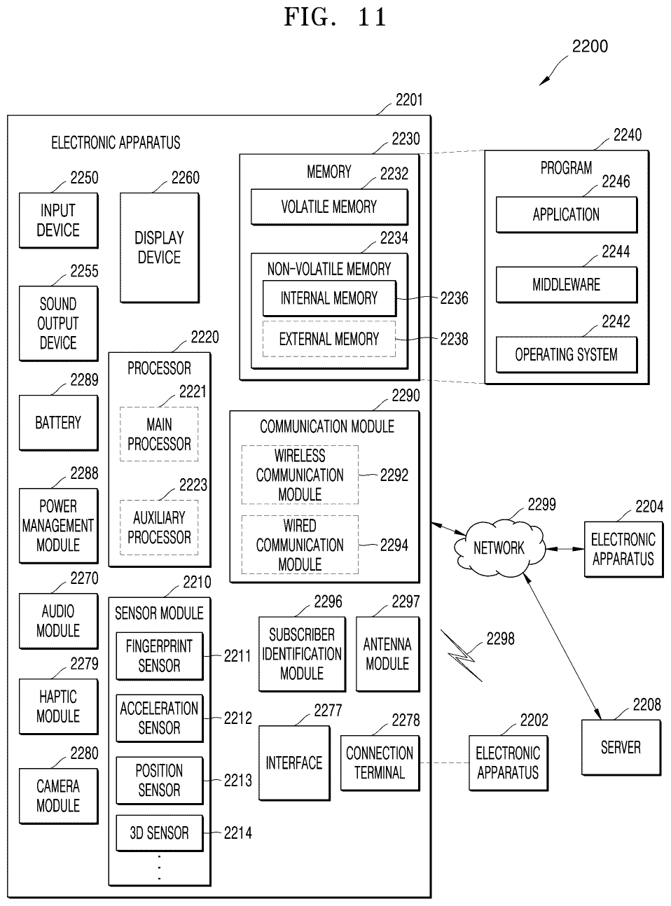

FIG. 11 is a block diagram showing a schematic configuration of a fourth electronic device according to an example embodiment.

Referring to FIG. 11, in a network environment 2200, the electronic apparatus 2201 may communicate with another electronic apparatus 2202 through a first network 2298 (a short-range wireless communication network, etc.) or communicate with another electronic device 2204 and/or a server 2208 through a second network 2299 (a long-range wireless communication network, etc.). The electronic apparatus 2201 may communicate with the electronic device 2204 via the server 2208. The electronic apparatus 2201 may include a processor 2220, a memory 2230, an input device 2250, a sound output device 2255, a display device 2260, an audio module 2270, a sensor module 2210, an interface 2277, a haptic module 2279, a camera module 2280, a power management module 2288, a battery 2289, a communication module 2290, a subscriber identification module 2296, and/or an antenna module 2297. In the electronic apparatus 2201, some (the display device 2260, etc.) of the components may be omitted or another component may be added. Some of the components may be configured as one integrated circuit. For example, a fingerprint sensor 2211, an iris sensor, an illumination sensor, etc., of the sensor module 2210 may be implemented in a form embedded in the display device 2260 (a display, etc.).

The processor 2220 may control one or more components (hardware, software components, etc.) of the electronic apparatus 2201 connected to the processor 2220 by executing software (the program 2240, etc.), and may perform various data processes or operations. As a part of the data processes or operations, the processor 2220 may load a command and/or data received from another component (the sensor module 2210, the communication module 2290, etc.) to a volatile memory 2232, may process the command and/or data stored in the volatile memory 2232, and may store result data in a non-volatile memory 2234. The processor 2220 may include a main processor 2221 (a central processing unit, an application processor, etc.) and an auxiliary processor 2223 (a graphics processor unit (GPU), an image signal processor, a sensor hub processor, a communication processor, etc.) that may operate independently of or along with the main processor 2221. The auxiliary processor 2223 may use less power than that of the main processor 2221 and may perform specified functions.

The auxiliary processor 2223, on behalf of the main processor 2221 while the main processor 2221 is in an inactive state (a sleep state), or along with the main processor 2221 while the main processor 2221 is in an active state (an application executed state), may control functions and/or states related to some (the display device 2260, the sensor module 2210, the communication module 2290, etc.) of the components of the electronic apparatus 2201. The auxiliary processor 2223 (the image signal processor, the communication processor, etc.) may be implemented as a part of another component (the camera module 2280, the communication module 2290, etc.) that is functionally related thereto.

The memory 2230 may store various data required by the components (the processor 2220, the sensor module 2276, etc.) of the electronic apparatus 2201. The data may include, for example, software (the program 2240, etc.) and input data and/or output data about commands related thereto. The memory 2230 may include the volatile memory 2232 or the non-volatile memory 2234. The non-volatile memory 2234 may include an internal memory 2236 and an external memory 2238. The program 2240 may be stored as software in the memory 2230, and may include an operating system 2242, middleware 2244, and/or an application 2246.

The input device 2250 may receive commands and/or data to be used in the components (the processor 2220, etc.) of the electronic apparatus 2201, from the outside (a user, etc.) of the electronic apparatus 2201. The input device 2250 may include a microphone, a mouse, a keyboard, and/or a digital pen (a stylus pen).

The sound output device 2255 may output a sound signal to the outside of the electronic apparatus 2201. The sound output device 2255 may include a speaker and/or a receiver. The speaker may be used for a general purpose such as multimedia reproduction or record play, and the receiver may be used to receive a call. The receiver may be coupled as a part of the speaker or may be implemented as an independent separate device.

The display device 2260 may provide visual information to the outside of the electronic apparatus 2201. The display device 2260 may include a display, a hologram device, or a projector, and a control circuit for controlling the corresponding device. The display device 2260 may include a touch circuitry configured to sense a touch, and/or a sensor circuit (a pressure sensor, etc.) that is configured to measure a strength of a force generated by the touch.

The audio module 2270 may convert sound into an electrical signal or vice versa. The audio module 2270 may acquire sound through the input device 2250 or may output sound via the sound output device 2255 and/or a speaker and/or a headphone of another electronic apparatus (the electronic apparatus 2202, etc.) connected directly or wirelessly to the electronic apparatus 2201.

The sensor module 2210 may sense an operating state (power, temperature, etc.) of the electronic apparatus 2201, or an outer environmental state (a user state, etc.), and may generate an electrical signal and/or a data value corresponding to the sensed state. The sensor module 2210 may include the fingerprint sensor 2211, an acceleration sensor 2212, a position sensor 2213, a three-dimensional (3D) sensor 2214, etc., and may also include an iris sensor, a gyro sensor, a pressure sensor, a magnetic sensor, a grip sensor, a proximity sensor, a color sensor, an infrared (IR) sensor, a biometric sensor, a temperature sensor, a humidity sensor, and/or an illumination sensor.

The 3D sensor 2214 may sense a shape, a motion, etc., of a subject by irradiating certain light to the subject and analyzing the light reflected from the subject and may include a meta-optical element.

The interface 2277 may support one or more designated protocols that may be used in order for the electronic apparatus 2201 to be directly or wirelessly connected to another electronic apparatus (the electronic apparatus 2202, etc.). The interface 2277 may include a high-definition multimedia interface (HDMI), a universal serial bus (USB) interface, a secure digital (SD) card interface, and/or an audio interface.

The connection terminal 2278 may include a connector by which the electronic apparatus 2201 may be physically connected to another electronic apparatus (the electronic apparatus 2202, etc.). The connection terminal 2278 may include an HDMI connector, a USB connector, an SD card connector, and/or an audio connector (a headphone connector, etc.).

The haptic module 2279 may convert the electrical signal into a mechanical stimulation (vibration, motion, etc.) or an electric stimulation that the user may sense through a tactile or motion sensation. The haptic module 2279 may include a motor, a piezoelectric device, and/or an electric stimulus device.

The camera module 2280 may capture a still image and a moving image. The camera module 2280 may include a lens assembly including one or more lenses, image sensors, image signal processors, and/or flashes. The lens assembly included in the camera module 2280 may collect light emitted from an object that is an object to be captured.

The power management module 2288 may manage power supplied to the electronic apparatus 2201. The power management module 2288 may be implemented as a part of a power management integrated circuit (PMIC).

The battery 2289 may supply electric power to components of the electronic apparatus 2201. The battery 2289 may include a primary battery that is not rechargeable, a secondary battery that is rechargeable, and/or a fuel cell.

The communication module 2290 may support establishment of a direct (wired) communication channel and/or a wireless communication channel between the electronic apparatus 2201 and another electronic apparatus (the electronic apparatus 2202, the electronic device 2204, the server 2208, etc.), and execution of communication through the established communication channel. The communication module 2290 may operate independently of the processor 2220 (the application processor, etc.), and may include one or more communication processors that support the direct communication and/or the wireless communication. The communication module 2290 may include a wireless communication module 2292 (a cellular communication module, a short-range wireless communication module, a global navigation satellite system (GNSS) communication module) and/or a wired communication module 2294 (a local area network (LAN) communication module, a power line communication module, etc.). From among the communication modules, a corresponding communication module may communicate with another electronic device via a first network 2298 (a short-range communication network such as Bluetooth, Wireless Fidelity (WiFi) Direct, or Infrared Data Association (IrDA)) or a second network 2299 (a long-range communication network such as a cellular network, Internet, or a computer network (LAN, a wide area network (WAN), etc.)). Such various kinds of communication modules may be integrated as one component (a single chip, etc.) or may be implemented as a plurality of components (a plurality of chips) separately from one another. The wireless communication module 2292 may identify and authenticate the electronic apparatus 2201 in a communication network such as the first network 2298 and/or the second network 2299 by using subscriber information (an international mobile subscriber identifier (IMSI), etc.) stored in the subscriber identification module 2296.

The antenna module 2297 may transmit or receive a signal and/or power to/from outside (another electronic device, etc.). An antenna may include a radiator formed as a conductive pattern formed on a substrate (a printed circuit board (PCB), etc.). The antenna module 2297 may include one or more antennas. When the antenna module 2297 includes a plurality of antennas, an antenna that is suitable for a communication scheme used in the communication network such as the first network 2298 and/or the second network 2299 may be selected by the communication module 2290 from among the plurality of antennas. The signal and/or the power may be transmitted between the communication module 2290 and another electronic device via the selected antenna. Another component (a radio frequency integrated circuit (RFIC), etc.) other than the antenna may be included as a part of the antenna module 2297.

Some of the components may be connected to one another via a communication scheme between peripheral devices (a bus, general purpose input and output (GPIO), a serial peripheral interface (SPI), a mobile industry processor interface (MIPI), etc.) and may exchange signals (commands, data, etc.).

The command or data may be transmitted or received between the electronic apparatus 2201 and the external electronic apparatus 2204 via the server 2208 connected to the second network 2299. Other electronic apparatuses 2202 and 2204 may be apparatuses of types that are the same as or different from the electronic apparatus 2201. All or some of operations executed in the electronic apparatus 2201 may be executed in one or more devices among the other electronic apparatuses 2202, 2204, and server 2208. For example, when the electronic apparatus 2201 has to perform a certain function or service, the electronic apparatus 2201 may request one or more other electronic devices (e.g., 2204) and server 2208 to perform some or entire function or service, instead of executing the function or service by itself. One or more electronic apparatuses (or devices) receiving the request execute an additional function or service related to the request and may transfer a result of the execution to the electronic apparatus 2201. For this end, cloud computing, distributed computing, and/or a client-server computing technique may be used.

In the network environment 2200, at least the electronic apparatus 2201 may include a switching device (e.g., a transistor) which may include any one of the HEMTs according to the above-described embodiments.

Any or all of the elements described with reference to FIG. 11 may communicate with any or all other elements described with reference to FIG. 11. For example, any element may engage in one-way and/or two-way and/or broadcast communication with any or all other elements in FIG. 11, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

Although many matters are specifically described in the foregoing description, they should be interpreted as an example of an example embodiment, rather than limiting the scope of the disclosure. Therefore, the scope of the disclosure should not be determined by the described embodiments, but by the technical spirit set forth in the claims.

The disclosed HEMT may include a compound semiconductor layer (e.g., AlGaN) serving as a Schottky barrier in a p-GaN gate stack forming an ohmic contact with a gate electrode. Thus, accumulation of a hole in p-GaN may be controlled and a gate leakage current may be reduced. By controlling the accumulation of the hole in p-GaN, degradation of a threshold voltage with respect to hole accumulation may be prevented, thereby stably maintaining a threshold voltage of the HEMT.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU) , an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A high electron mobility transistor (HEMT) comprising:
a channel layer comprising a two-dimensional (2D) electron gas (2DEG) as a channel carrier;
a first electrode and a second electrode separated from each other on the channel layer;
a first semiconductor layer on the channel layer between the first electrode and the second electrode, a band gap of the first semiconductor layer being greater than a band gap of the channel layer;
a gate stack on the first semiconductor layer; and
a gate electrode in ohmic contact with the gate stack, wherein
the gate stack includes a lower layer contacting the first semiconductor layer, a second semiconductor layer on the lower layer, and an upper layer on the second semiconductor layer,
a band gap of the lower layer is less than a band gap of the first semiconductor layer,
the lower layer is doped with a p-type dopant,
the second semiconductor layer is a Schottky barrier on the lower layer,
a band gap of the second semiconductor layer is greater than a band gap of the lower layer,
a band gap of the upper layer is less than a band gap of the second semiconductor layer, and
the upper layer is doped with a p-type dopant.

2. The HEMT of claim 1, wherein a thickness of the second semiconductor layer is thicker than a thickness of the first semiconductor layer.

3. The HEMT of claim 1, wherein a doping concentration of the upper layer is greater than a doping concentration of the lower layer.

4. The HEMT of claim 1, wherein
the gate stack further comprises a third semiconductor layer separated from the second semiconductor layer, and
the third semiconductor layer is between the second semiconductor layer and the upper layer, and
a band gap of the third semiconductor layer is greater than a band gap of the lower layer and a band gap of the upper layer.

5. The HEMT of claim 4, wherein a thickness of the second semiconductor layer and a thickness of the third semiconductor layer are equal to each other.

6. The HEMT of claim 4, wherein a thickness of the second semiconductor layer and a thickness of the third semiconductor layer are different from each other.

7. The HEMT of claim 4, wherein a material of the second semiconductor layer and a material of the third semiconductor layer are identical to each other.

8. The HEMT of claim 4, wherein the second semiconductor layer and the third semiconductor layer are thicker than the first semiconductor layer.

9. The HEMT of claim 4, wherein the second semiconductor layer and the third semiconductor layer comprise compound semiconductors.

10. The HEMT of claim 9, wherein the compound semiconductors comprise a ternary compound semiconductor comprising a Group III-V element.

11. The HEMT of claim 4, wherein
the gate stack further includes an intermediate layer between the second semiconductor layer and the third semiconductor layer,
a band gap of the intermediate layer is less than the band gap of the second semiconductor layer and the band gap of the third semiconductor layer, and
the intermediate layer is doped with a p-type dopant.

12. The HEMT of claim 11, wherein a thickness of the upper layer is less than the thickness of the lower layer and a thickness of the intermediate layer.

13. The HEMT of claim 11, wherein
a doping concentration of the intermediate layer and a doping concentration of the lower layer are less than a doping concentration of the upper layer.

14. The HEMT of claim 11, wherein the lower layer, the intermediate layer, and the upper layer comprise compound semiconductors of identical components.

15. The HEMT of claim 1, wherein the first semiconductor layer and the second semiconductor layer comprise identical compound semiconductors.

16. The HEMT of claim 15, wherein the first semiconductor layer and the second semiconductor layer each comprise a ternary compound semiconductor comprising a Group III-V element.

17. The HEMT of claim 1, wherein the lower layer and the upper layer comprise a binary nitride comprising an identical element of a Group III-V.

18. The HEMT of claim 17, wherein the binary nitride comprises GaN.

19. The HEMT of claim 1, wherein
the lower layer, the upper layer, and the second semiconductor layer comprise Group III-V ternary compound semiconductors of identical components comprising aluminum, and
an aluminum content of the second semiconductor layer is greater than an aluminum content of the lower layer and an aluminum content of the upper layer.

20. An electronic device comprising:
a plurality of high electron mobility transistors (HEMTs) having different threshold voltages, wherein
one of the plurality of HEMTs comprises the HEMT of claim 1.
